(19) United States
(12) Patent Application Publication
(10) Pub. No.: US 2025/0261420 A1
(43) Pub. Date: Aug. 14, 2025

(54) SEMICONDUCTOR DEVICE AND MANUFACTURING METHOD FOR THE SAME

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Hiroshi ONO, Setagaya (JP); Daimotsu KATO, Kawasaki (JP); Yosuke KAJIWARA, Yokohama (JP); Aya SHINDOME, Yokohama (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/016,963

(22) Filed: Jan. 10, 2025

(30) Foreign Application Priority Data
Feb. 14, 2024 (JP) 2024-020607

(51) Int. Cl. H10D 62/854; H10D 62/85; H10D 64/27

(52) U.S. Cl. CPC H10D 62/854; H10D 62/8503; H10D 64/518

(57) ABSTRACT

According to one embodiment, a semiconductor device includes a first electrode, a second electrode, a third electrode, a semiconductor member, and a first insulating member. The third electrode includes silicon. The third electrode includes first and second electrode regions. The semiconductor member includes first and semiconductor layers. The first semiconductor layer includes Alₓ₁Ga₁₋ₓ₁N (0≤x1<1), and includes first to fifth partial regions. The second semiconductor layer includes Alₓ₂Ga₁₋ₓ₂N (0<x2≤1, x1<x2), and includes first and second semiconductor portions. The first electrode region includes a first region between the third partial region and the second electrode region in the second direction, a second region between the first semiconductor portion and the second electrode region in the first direction, and a third region between the second electrode region and the second semiconductor portion in the first direction.

### CROSS-REFERENCE TO RELATED APPLICATIONS

This application is based upon and claims the benefit of priority from Japanese Patent Application No. 2024-020607, filed on Feb. 14, 2024; the entire contents of which are incorporated herein by reference.

### FIELD

Embodiments described herein relate generally to a semiconductor device and a manufacturing method for the same.

### BACKGROUND

For example, it is desired to improve the characteristics of semiconductor devices such as transistors.

### BRIEF DESCRIPTION OF THE DRAWINGS

FIG. 1 is a schematic cross-sectional view illustrating a semiconductor device according to a first embodiment;

FIG. 2 is a schematic cross-sectional view illustrating a part of the semiconductor device according to the first embodiment;

FIGS. 3A to 3C are schematic diagrams illustrating the semiconductor device according to the first embodiment;

FIGS. 4A to 4C are schematic diagrams illustrating a semiconductor device according to the first embodiment;

FIGS. 5A and 5B illustrate the method for manufacturing a semiconductor device according to a second embodiment;

FIGS. 6A and 6B illustrate the method for manufacturing the semiconductor device according to the second embodiment; and

FIGS. 7A, and 7B illustrate the method for manufacturing the semiconductor device according to the second embodiment.

### DETAILED DESCRIPTION

According to one embodiment, a semiconductor device includes a first electrode, a second electrode, a third electrode, a semiconductor member, and a first insulating member. The third electrode includes silicon. A position of the third electrode in a first direction from the first electrode to the second electrode is between a position of the first electrode in the first direction and a position of the second electrode in the first direction. The third electrode includes a first electrode region and a second electrode region. The semiconductor member includes a first semiconductor layer and a second semiconductor layer. The first semiconductor layer includes Alₓ₁Ga₁₋ₓ₁N (0≤x1<1). The first semiconductor layer includes a first partial region, a second partial region, a third partial region, a fourth partial region, and a fifth partial region. A second direction from the first partial region to the first electrode crosses the first direction. A direction from the second partial region to the second electrode is along the second direction. A direction from the third partial region to the third electrode is along the second direction. A position of the fourth partial region in the first direction is between a position of the first partial region in the first direction and a position of the third partial region in the first direction. A position of the fifth partial region in the first direction is between the position of the third partial region in the first direction and a position of the second partial region in the first direction. The second semiconductor layer includes Alₓ₂Ga₁₋ₓ₂N (0<x2≤1, x1<x2). The second semiconductor layer includes a first semiconductor portion and a second semiconductor portion. A direction from the fourth partial region to the first semiconductor portion is along the second direction. A direction from the fifth partial region to the second semiconductor portion is along the second direction. The first insulating member is provided between the semiconductor member and the third electrode. A first concentration of a first element in the first electrode region is different from a second concentration of the first element in the second electrode region. The first element includes at least one selected from the group consisting of B, Ga, In, and Al. The first electrode region includes a first region between the third partial region and the second electrode region in the second direction, a second region between the first semiconductor portion and the second electrode region in the first direction, and a third region between the second electrode region and the second semiconductor portion in the first direction. A first thickness of the first region along the second direction is 30 nm or more.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

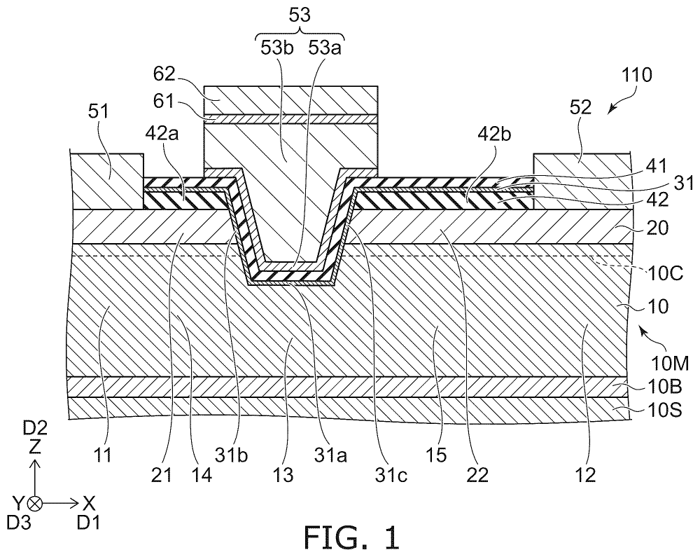

FIG. 1 is a schematic cross-sectional view illustrating a semiconductor device according to a first embodiment.

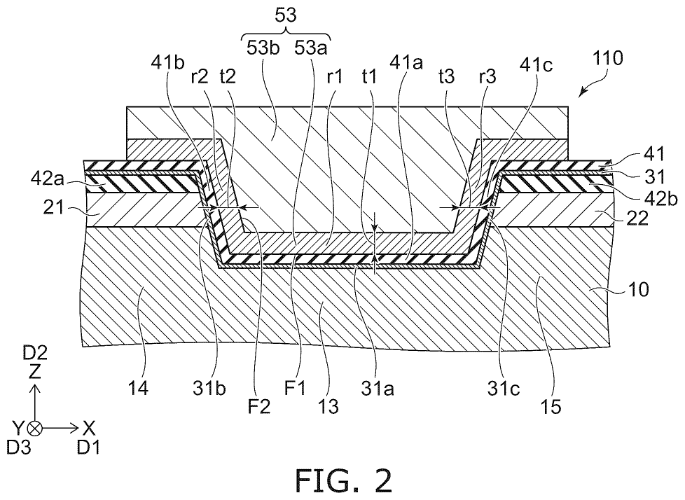

FIG. 2 is a schematic cross-sectional view illustrating a part of the semiconductor device according to the first embodiment.

As shown in FIG. 1, a semiconductor device 110 according to the embodiment includes a first electrode 51, a second electrode 52, a third electrode 53, a semiconductor member 10M, and a first insulating member 41.

The third electrode 53 includes silicon. Third electrode 53 includes, for example, polysilicon.

A first direction D1 from the first electrode 51 to the second electrode 52 is defined as an X-axis direction. One direction perpendicular to the X-axis direction is defined as a Z-axis direction. A direction perpendicular to the X-axis direction and the Z-axis direction is defined as a Y-axis direction.

A position of the third electrode 53 in the first direction D1 is between a position of the first electrode 51 in the first direction D1 and a position of the second electrode 52 in the first direction D1. The third electrode 53 includes a first electrode region 53a and a second electrode region 53b.

The semiconductor member 10M includes a first semiconductor layer 10 and a second semiconductor layer 20.

The first semiconductor layer 10 includes Alₓ₁Ga₁₋ₓ₁N (0≤x1<1). In one example, the composition ratio x1 may be not less than 0 and less than 0.15. The first semiconductor layer 10 may be, for example, a GaN layer.

The first semiconductor layer 10 includes a first partial region 11, a second partial region 12, a third partial region 13, a fourth partial region 14, and a fifth partial region 15. A second direction D2 from the first partial region 11 to the first electrode 51 crosses the first direction D1. The second direction D2 may be, for example, the Z-axis direction.

A direction from the second partial region 12 to the second electrode 52 is along the second direction D2. A direction from the third partial region 13 to the third electrode 53 is along the second direction D2. A position of the fourth partial region 14 in the first direction D1 is between a position of the first partial region 11 in the first direction D1 and a position of the third partial region 13 in the first direction D1. A position of the fifth partial region 15 in the first direction D1 is between the position of the third partial region 13 in the first direction D1 and a position of the second partial region 12 in the first direction D1. The boundaries between these partial regions may be clear or unclear.

For example, a region that overlaps the first electrode 51 in the second direction D2 corresponds to the first partial region 11. For example, a region that overlaps the second electrode 52 in the second direction D2 corresponds to the second partial region 12. For example, a region that overlaps at least a part of the third electrode 53 in the second direction D2 corresponds to the third partial region 13.

The second semiconductor layer 20 includes Alₓ₂Ga₁₋ₓ₂N (0<x2≤1, x1<x2). The composition ratio x2 may be, for example, not less than 0.15 and not more than 0.40. The second semiconductor layer 20 may be, for example, an AlGaN layer.

The second semiconductor layer 20 includes a first semiconductor portion 21 and a second semiconductor portion 22. A direction from the fourth partial region 14 to the first semiconductor portion 21 is along the second direction D2. A direction from the fifth partial region 15 to the second semiconductor portion 22 is along the second direction D2. For example, the first electrode 51 is electrically connected to the first semiconductor portion 21. For example, the second electrode 52 is electrically connected to the second semiconductor portion 22.

The first insulating member 41 is provided between the semiconductor member 10M and the third electrode 53. At least a part of the third electrode 53 is provided between the first semiconductor portion 21 and the second semiconductor portion 22 in the second direction D2. At least a part of the third electrode 53 may be provided between a part of the fourth partial region 14 and a part of the fifth partial region 15 in the second direction D2.

The current flowing between the first electrode 51 and the second electrode 52 can be controlled by a potential of the third electrode 53. For example, the potential of the third electrode 53 may be based on a potential of the first electrode 51. The first electrode 51 functions, for example, as a source electrode. The second electrode 52 functions, for example, as a drain electrode. The third electrode 53 functions as, for example, a gate electrode. The semiconductor device 110 is, for example, a transistor. The third electrode 53 is, for example, a recessed gate electrode. For example, normally-off operation is obtained.

The first semiconductor layer 10 includes a portion facing the second semiconductor layer 20. A carrier region 10C is formed in this portion. The carrier region 10C is, for example, a two-dimensional electron gas. The semiconductor device 110 is, for example, a HEMT (High Electron Mobility Transistor).

A distance between the first electrode 51 and the third electrode 53 along the first direction D1 is shorter than a distance between the third electrode 53 and the second electrode 52 along the first direction D1. Thereby, it becomes easy to obtain stable operation. The first electrode 51, the second electrode 52, and the third electrode 53 may extend along a third direction D3. The third direction D3 crosses a plane including the first direction D1 and the second direction D2. The third direction D3 may be, for example, the Y-axis direction.

As shown in FIG. 2, the first electrode region 53a includes a first region r1, a second region r2, and a third region r3. The first region r1 is provided between the third partial region 13 and the second electrode region 53b in the second direction D2. The second region r2 is provided between the first semiconductor portion 21 and the second electrode region 53b in the first direction D1. The third region r3 is provided between the second electrode region 53b and the second semiconductor portion 22 in the first direction D1.

As shown in FIG. 2, the first insulating member 41 includes a first insulating region 41a, a second insulating region 41b, and a third insulating region 41c. The first insulating region 41a is provided between the third partial region 13 and the third electrode 53 in the second direction D2. The second insulating region 41b is provided between the first semiconductor portion 21 and the third electrode 53 in the first direction D1. The third insulating region 41c is provided between the third electrode 53 and the second semiconductor portion 22 in the second direction D2.

For example, the first region r1 is provided between the first insulating region 41a and the second electrode region 53b in the second direction D2. The second region r2 is provided between the second insulating region 41b and the second electrode region 53b in the first direction D1. The third region r3 is provided between the second electrode region 53b and the third insulating region 41c in the first direction D1.

A first concentration of a first element in the first electrode region 53a is different from a second concentration of the first element in the second electrode region 53b. The first element is at least one selected from the group consisting of B, Ga, In, and Al. The first element provides conductivity to the first electrode region 53a and to the second electrode region 53b.

In the embodiment, the third electrode 53 includes a plurality of electrode regions (a first electrode region 53a and a second electrode region 53b). With this configuration, stable characteristics can be obtained at the bottom of the third electrode 53 and the sides of the third electrode 53.

For example, in a first reference example, the third electrode 53 is one electrode region (one layer). For example, the first element is introduced into the silicon layer that will become the third electrode 53 by ion implantation. In this case, it is difficult to obtain a uniform concentration of the first element at the bottom of the third electrode 53 and at the sides of the third electrode 53. In the first reference example, it is difficult to obtain the desired characteristics.

For example, in a second reference example, the third electrode 53 is one electrode region (one layer). For example, the silicon layer that becomes the third electrode 53 is formed using a source gas including the first element and a source gas including silicon. In this case, heat treatment is performed at high temperature and for a long time in order to activate the first element. Due to the heat treatment, Ga and the like in the semiconductor member 10M are diffused, making it difficult to obtain the desired characteristics. Due to the heat treatment, Si or the first element included in the silicon layer that becomes the third electrode 53 may diffuse toward the first insulating member 41 or the semiconductor member 10M, making it difficult to obtain the desired characteristics.

In the embodiment, the third electrode 53 includes a plurality of electrode regions (the first electrode region 53a and the second electrode region 53b). It is sufficient if the concentration of the first element is uniform in the region (first electrode region 53a) of the third electrode 53 that faces the semiconductor member 10M. Thereby, for example, in the region (first electrode region 53a) of the third electrode 53 facing the semiconductor member 10M, uniform surface characteristics (work function, etc.) can be easily obtained stably. As a result, stable characteristics (e.g., threshold voltage, etc.) can be obtained. On the other hand, the second electrode region 53b functions as a layer that reduces the electrical resistance of the third electrode 53. In the embodiments, for example, a stable threshold voltage and low electrical resistance are obtained. According to the embodiment, a semiconductor device with improved characteristics can be provided.

In one example, the silicon layer serving as the first electrode region 53a may be formed using a source gas including the first element and a source gas including silicon. A silicon layer may be formed on the first electrode region 53a, and the first element may be introduced into the silicon layer by ion implantation. Thereby, the second electrode region 53b is formed. Since the first electrode region 53a is thin, the heat treatment can be performed in a short time. The diffusion of Ga and the like in the semiconductor member 10M is suppressed. In the second electrode region 53b, the requirement for uniformity of the concentration distribution of the first element is relaxed. Manufacturing becomes easier.

As shown in FIG. 2, a thickness of the first region r1 along the second direction D2 is defined as a first thickness t1. The first thickness t1 is, for example, 30 nm or more. This provides stable film quality. Uniform characteristics are easily obtained at the bottom of the third electrode 53.

A thickness of the second region r2 along the first direction D1 is defined as a second thickness t2. The second thickness t2 is, for example, 30 nm or more. This provides stable film quality. Uniform characteristics can easily be obtained on the side portions of the third electrode 53.

A thickness of the third region r3 along the first direction D1 is defined as a third thickness t3. The third thickness t3 is, for example, 30 nm or more. This provides stable film quality. Uniform characteristics can easily be obtained on the side portions of the third electrode 53.

The first thickness t1 may be, for example, 150 nm or less. The second thickness t2 may be, for example, 150 nm or less. The third thickness t3 may be, for example, 150 nm or less. By not having these thicknesses excessively, for example, the temperature and time of the heat treatment can be moderated.

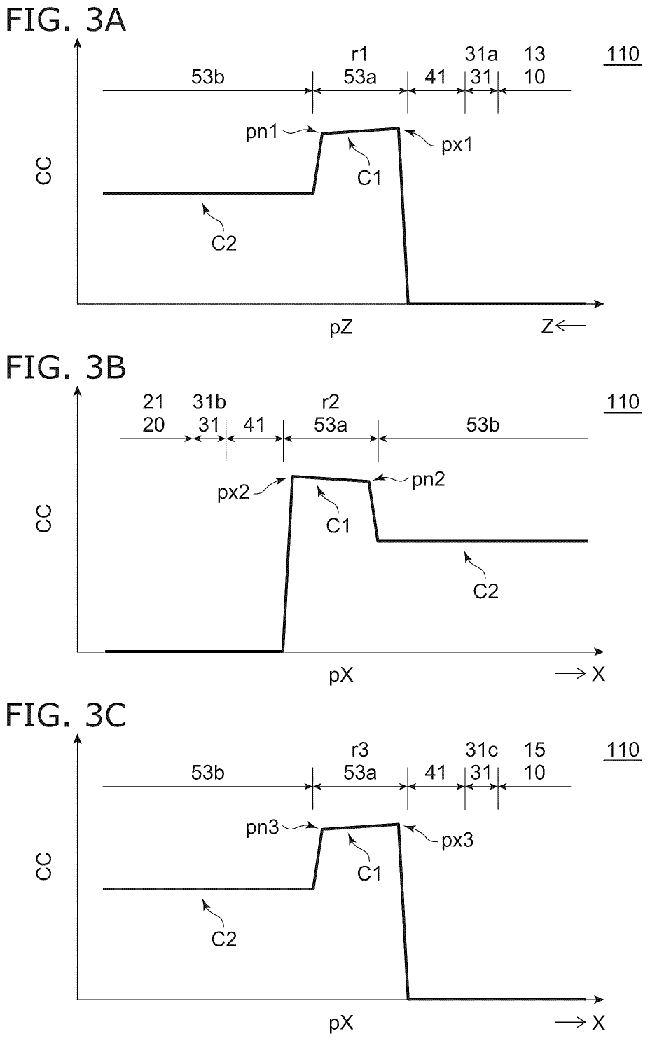

FIGS. 3A to 3C are schematic diagrams illustrating the semiconductor device according to the first embodiment.

FIG. 3A schematically shows the profile of the first element in a portion including the first region r1. FIG. 3B schematically shows the profile of the first element in a portion including the second region r2. FIG. 3C schematically shows the profile of the first element in a portion including the third region r3. The horizontal axis in FIG. 3A is the position pZ in the Z-axis direction. The horizontal axis in FIGS. 3B and 3C is the position pX in the X-axis direction. The vertical axis of these figures is the concentration CC of the first element.

As shown in FIGS. 3A to 3C, the first concentration C1 of the first element in the first electrode region 53a is different from the second concentration C2 of the first element in the second electrode region 53b. In this example, the first concentration C1 is higher than the second concentration C2. A high work function is easily obtained in the first electrode region 53a where the first concentration C1 is high. Thereby, it becomes easy to obtain a high threshold voltage. For example, stable normally-off operation can be easily obtained.

For example, the first concentration C1 may be not less than 1.3 times and not more than 30 times the second concentration C2. For example, it is easy to obtain a high threshold voltage. For example, it is easy to obtain low electrical resistance in the second electrode region 53b.

The concentration of the first element in the first electrode region 53a may be substantially constant. For example, as shown in FIG. 3A, the maximum value of the concentration CC of the first element in the first region r1 is defined as a first maximum value px1. The minimum value of the concentration CC of the first element in the first region r1 is defined as a first minimum value pn1. A first ratio of the difference between the first maximum value px1 and the first minimum value pn1 to the first maximum value pn1 may be 0.1 or less.

The first concentration C1 may be ½ of the sum of the first maximum value px1 and the first minimum value pn1. The first maximum value px1 may be, for example, not less than 5×10²⁰ cm⁻³ and not more than 5×10²¹ cm⁻³. In one example, the first concentration C1 is not less than 5×10²⁰ cm⁻³ and not more than 5×10²¹ cm⁻³. The position in the Z-axis direction corresponding to the first maximum value px1 and the position in the Z-axis direction corresponding to the first minimum value pn1 may be any position in the first region r1.

As shown in FIG. 3B, the maximum value of the concentration CC of the first element in the second region r2 is defined as a second maximum value px2. The minimum value of the concentration CC of the first element in the second region r2 is defined as a second minimum value pn2. A second ratio of the difference between the second maximum value px2 and the second minimum value pn2 to the second minimum value pn2 may be 0.1 or less. The second maximum value px2 may be, for example, not less than 5×10²⁰ cm⁻³ and not more than 5×10²¹ cm⁻³. The position in the X-axis direction corresponding to the second maximum value px2 and the position in the X-axis direction corresponding to the second minimum value pn2 may be any position in the second region r2.

As shown in FIG. 3C, the maximum value of the concentration CC of the first element in the third region r3 is defined as a third maximum value px3. The minimum value of the concentration CC of the first element in the third region r3 is defined as a third minimum value pn3. A third ratio of the difference between the third maximum value px3 and the third minimum value pn3 to the third minimum value pn3 is 0.1 or less. The third maximum value px3 may be, for example, not less than 5×10²⁰ cm⁻³ and not more than 5×10²¹ cm⁻³. The position in the X-axis direction corresponding to the third maximum value px3 and the position in the X-axis direction corresponding to the third minimum value pn3 may be any position in the third region r3.

In the embodiment, a second size of the second crystal grains in the second electrode region 53b may be larger than a first size of the first crystal grains in the first electrode region 53a. Since the second size is large, it is easy to obtain low electrical resistance in the second electrode region 53b. Since the first size is small, uniform characteristics can be easily obtained in the first electrode region 53a.

As shown in FIG. 2, the semiconductor device 110 may further include a first compound member 31. The first compound member 31 includes Al_{z1}Ga_{1-z1}N (x2<z1≤1). The composition ratio z1 may be, for example, not less than 0.85 and not more than 1. The first compound member 31 may be, for example, an AlN layer.

The first compound member 31 includes a first compound region 31a, a second compound region 31b, and a third compound region 31c. The first compound region 31a is provided between the third partial region 13 and the first insulating member 41 (for example, the first insulating region 41a) in the second direction D2. The second compound region 31b is provided between the first semiconductor portion 21 and the first insulating member 41 (second insulating region 41b) in the first direction D1. The third compound region 31c is provided between the first insulating member 41 (third insulating region 41c) and the second semiconductor portion 22 in the first direction D1.

As shown in FIG. 2, the third electrode 53 includes a first face F1 and a second face F2. The first face F1 faces the third partial region 13 in the second direction D2. The second face F2 faces the first semiconductor portion 21 in the first direction D1. The second face F2 may be inclined with respect to the first face F1. The second face F2 may be substantially perpendicular to the first face F1.

As shown in FIG. 1, the semiconductor device 110 includes a first conductive layer 61 and a second conductive layer 62. The second electrode region 53b is provided between the first electrode region 53a and the second conductive layer 62. The first conductive layer 61 is provided between the second electrode region 53b and the second conductive layer 62. The first conductive layer 61 includes, for example, at least one selected from the group consisting of Ti, Ta, and W. The first conductive layer 61 may include, for example, TiN. The second conductive layer 62 includes, for example, at least one selected from the group consisting of Al, Cu, Au, Ag, and Ni. The first conductive layer 61 is a barrier metal. The second conductive layer 62 is, for example, a wiring layer.

As shown in FIG. 1, the semiconductor device 110 may include a base 10S and a nitride layer 10B. The nitride layer 10B is provided between the base 10S and the first semiconductor layer 10. The nitride layer 10B includes Al, Ga, and N. The nitride layer 10B is, for example, a buffer layer. For example, the nitride layer 10B is provided on the base 10S. The first semiconductor layer 10 is provided on the nitride layer 10B. The second semiconductor layer 20 is provided on the first semiconductor layer 10.

The semiconductor device 110 may further include a second insulating member 42. The second insulating member 42 includes a first insulating portion 42a and a second insulating portion 42b. The first semiconductor portion 21 is provided between the fourth partial region 14 and the first insulating portion 42a in the second direction D2. The second semiconductor portion 22 is provided between the fifth partial region 15 and the second insulating portion 42b in the second direction D2. The second insulating member 42 includes silicon and nitrogen, for example. The second insulating member 42 is, for example, silicon nitride. For example, the second semiconductor layer 20 is protected by the second insulating member 42.

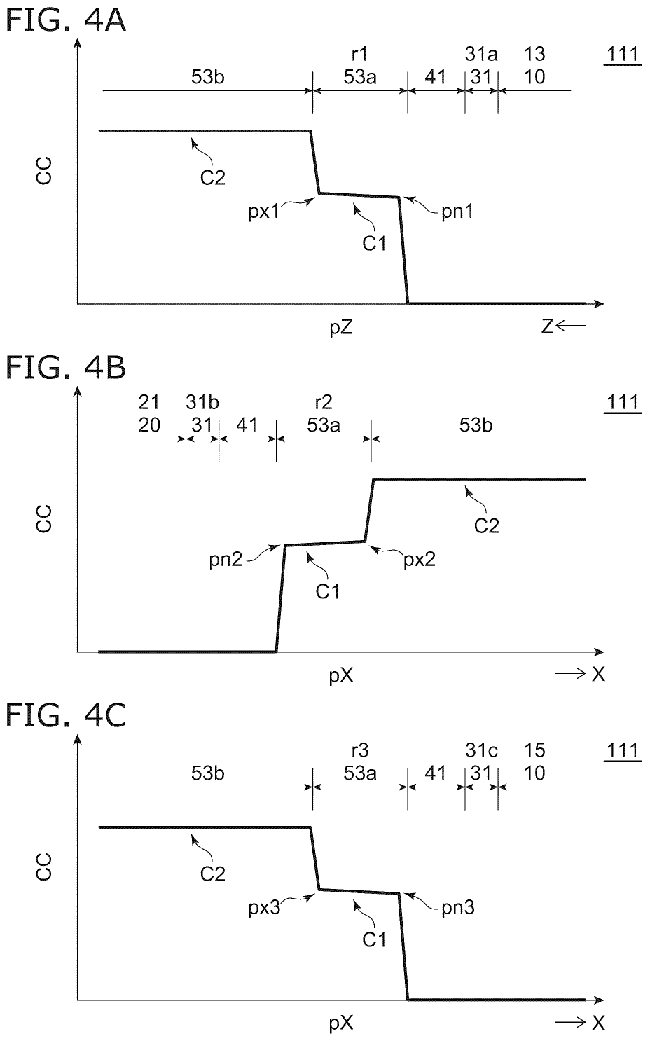

FIGS. 4A to 4C are schematic diagrams illustrating a semiconductor device according to the first embodiment.

These figures illustrate the profile of the first element in the semiconductor device 111 according to the embodiment.

FIG. 4A schematically shows the profile of the first element in a portion including the first region r1. FIG. 4B schematically shows the profile of the first element in a portion including the second region r2. FIG. 4C schematically shows the profile of the first element in a portion including the third region r3.

As shown in these figures, the first concentration C1 of the first element in the first electrode region 53a is different from the second concentration C2 of the first element in the second electrode region 53b. In the semiconductor device 111, the first concentration C1 is lower than the second concentration C2. The configuration of the semiconductor device 111 other than this may be the same as the configuration of the semiconductor device 110.

In the semiconductor device 111, the second concentration C2 is high. Thereby, the electrical resistance of the third electrode 53 can be reduced. In the semiconductor device 111, for example, the first concentration C1 is low. Thereby, the characteristics (e.g., electrical resistance, etc.) of the first electrode region 53a are optimized. Also in the semiconductor device 111, for example, an appropriate threshold voltage and low electrical resistance can be obtained. According to the embodiment, device a semiconductor with improved characteristics can be provided.

In the semiconductor device 111, the second concentration C2 may be not less than 1.3 times and not more than 30 times the first concentration C1.

In the semiconductor device 111, the concentration of the first element in the first electrode region 53a may be substantially constant. For example, as shown in FIG. 4A, a first ratio of a difference between the first maximum value px1 of the concentration CC of the first element in the first region r1 and the first minimum value pn1 of the concentration CC of the first element in the first region r1 to the first minimum value pn1 may be 0.1 or less.

The first concentration C1 may be ½ of the sum of the first maximum value px1 and the first minimum value pn1. The first maximum value px1 may be, for example, not less than 1×10¹⁹ cm⁻³ and not more than 1×10²⁰ cm⁻³. In one example, the first concentration C1 is not less than 1×10¹⁹ cm⁻³ and not more than 1×10²⁰ cm⁻³. The position in the Z-axis direction corresponding to the first maximum value px1 and the position in the Z-axis direction corresponding to the first minimum value pn1 may be any position in the first region r1.

As shown in FIG. 4B, the second ratio of the difference between the second maximum value px2 of the concentration CC of the first element in the second region r2 and the second minimum value pn2 of the concentration CC of the first element in the second region r2 to the second minimum value pn2 may be 0.1 or less. The second maximum value px2 may be, for example, not less than 1×10¹⁹ cm⁻³ and not more than 1×10²⁰ cm⁻³. The position in the X-axis direction corresponding to the second maximum value px2 and the position in the X-axis direction corresponding to the second minimum value pn2 may be any position in the second region r2.

As shown in FIG. 4C, the third ratio of the difference between the third maximum value px3 of the concentration CC of the first element in the third region r3 and the third minimum value pn3 of the concentration CC of the first element in the third region r3 to the third minimum value pn3 is 0.1 or less. The third maximum value px3 may be, for example, not less than 1×10¹⁹ cm⁻³ and not more than 1×10²⁰ cm⁻³. The position in the X-axis direction corresponding to the third maximum value px3 and the position in the X-axis direction corresponding to the third minimum value pn3 may be any position in the third region r3.

In the semiconductor device 111, the second size of the second crystal grains in the second electrode region 53b may be larger than the first size of the first crystal grains in the first electrode region 53a. Since the second size is large, it is easy to obtain low electrical resistance in the second electrode region 53b. Since the first size is small, uniform characteristics can be easily obtained in the first electrode region 53a.

### Second Embodiment

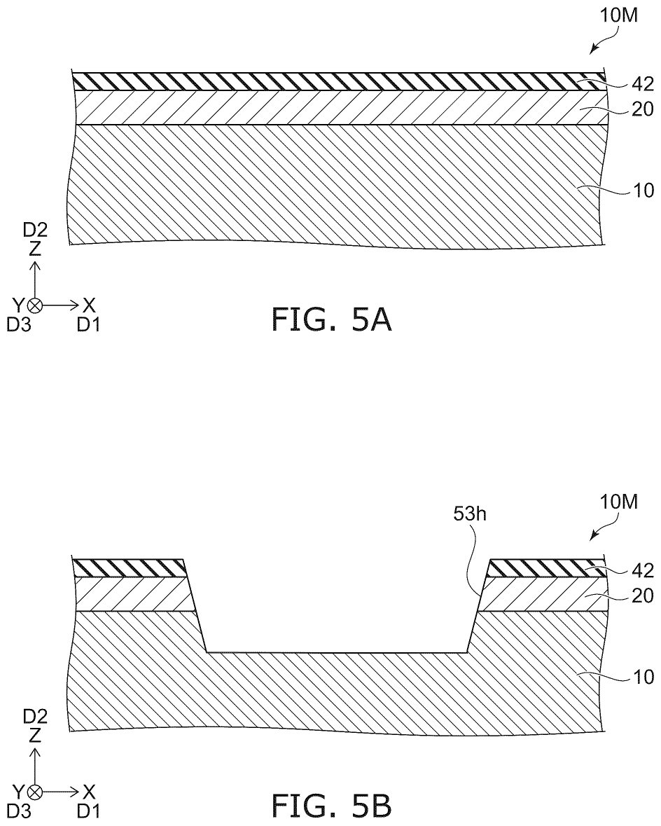

FIGS. 5A, 5B, 6A, 6B, 7A, and 7B illustrate the method for manufacturing a semiconductor device according to the second embodiment.

As shown in FIG. 5A, a semiconductor member 10M is prepared. The semiconductor member 10M includes the first semiconductor layer 10 and the second semiconductor layer 20 provided on the first semiconductor layer 10. The first semiconductor layer 10 includes Alₓ₁Ga₁₋ₓ₁N (0≤x1<1). The second semiconductor layer 20 includes Alₓ₂Ga₁₋ₓ₂N (0<x2≤1, x1<x2).

As shown in FIG. 5B, a part of the second semiconductor layer 20 is removed to form a hole 53h that reaches the first semiconductor layer 10.

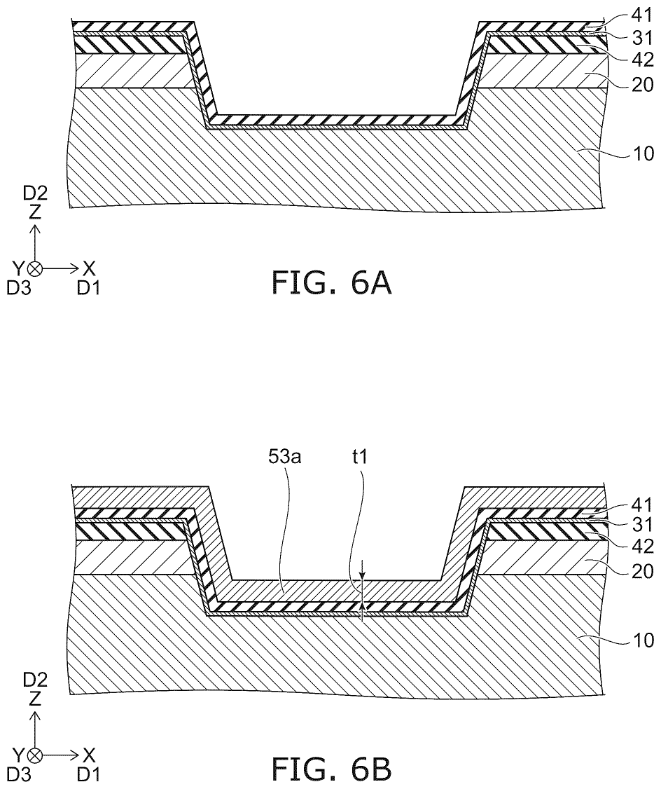

As shown in FIG. 6B, the first electrode region 53a is formed at the bottom of the hole 53h and the side face of the hole 53h. The first electrode region 53a includes the first element and silicon. The first element includes at least one selected from the group consisting of B, Ga, In, and Al. The first thickness t1 of the first electrode region 53a is 30 nm or more. The first electrode region 53a is formed by, for example, CVD (Chemical Vapor Deposition). The first electrode region 53a is formed by, for example, ALD (Atomic Layer Deposition).

As shown in FIG. 6A, in this example, the first compound member 31 and the first insulating member 41 are formed on the surface of the hole 53h between the formation of the hole 53h and the formation of the first electrode region 53a. Furthermore, the second insulating member 42 is formed between the formation of the hole 53h and the formation of the first compound member 31.

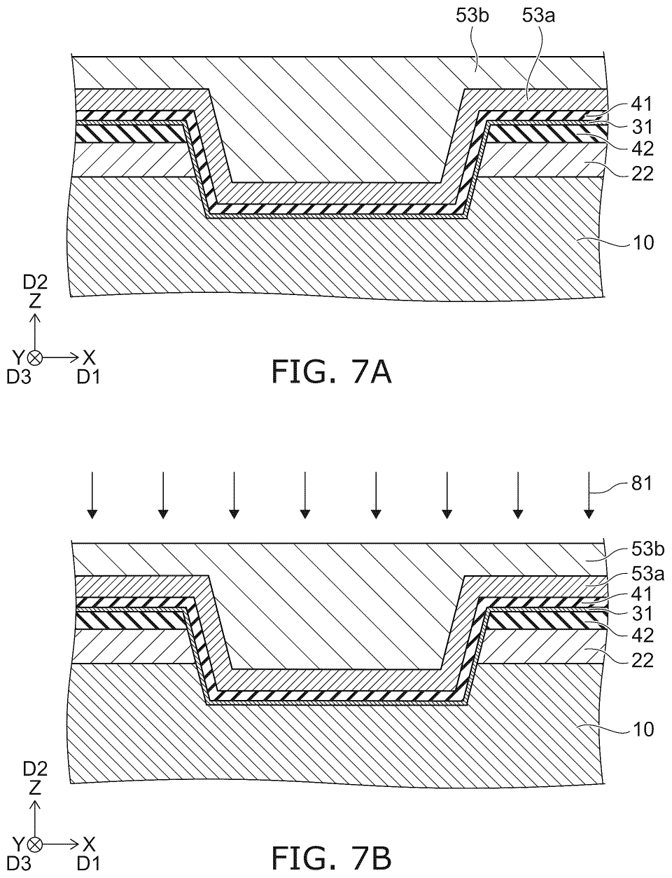

As shown in FIG. 7A, the second electrode region 53b including silicon is formed on the first electrode region 53a. The first electrode region 53a and the second electrode region 53b may be formed continuously.

As shown in FIG. 7B, the first element 81 is introduced (implanted, for example) into the second electrode region 53b. Thereafter, the third electrode 53 is obtained by processing the second electrode region 53b and the first electrode region 53a. Furthermore, the first electrode 51 and the second electrode 52 are formed. As a result, the semiconductor device 110 or the semiconductor device 111 is obtained.

In embodiments, information regarding the composition of the material is obtained by SIMS (Secondary Ion Mass Spectrometry), EDX (Energy dispersive X-ray spectroscopy), or the like. In the embodiments, information regarding length and thickness is obtained by electron microscopy or the like.

The embodiments may include the following Technical proposals:

### Technical Proposal 1

A semiconductor device, comprising:
a first electrode;
a second electrode;
a third electrode including silicon, a position of the third electrode in a first direction from the first electrode to the second electrode being between a position of the first electrode in the first direction and a position of the second electrode in the first direction, the third electrode including a first electrode region and a second electrode region;
a semiconductor member including a first semiconductor layer and a second semiconductor layer,
   the first semiconductor layer including Alₓ₁Ga₁₋ₓ₁N (0≤x1<1), the first semiconductor layer including a first partial region, a second partial region, a third partial region, a fourth partial region, and a fifth partial region, a second direction from the first partial region to the first electrode crossing the first direction, a direction from the second partial region to the second electrode being along the second direction, a direction from the third partial region to the third electrode being along the second direction, a position of the fourth partial region in the first direction being between a position of the first partial region in the first direction and a position of the third partial region in the first direction, a position of the fifth partial region in the first direction being between the position of the third partial region in the first direction and a position of the second partial region in the first direction;
   the second semiconductor layer including Alₓ₂Ga₁₋ₓ₂N (0<x2≤1, x1<x2), the second semiconductor layer including a first semiconductor portion and a second semiconductor portion, a direction from the fourth partial region to the first semiconductor portion being along the second direction, a direction from the fifth partial region to the second semiconductor portion being along the second direction; and 0
a first insulating member provided between the semiconductor member and the third electrode;
a first concentration of a first element in the first electrode region being different from a second concentration of the first element in the second electrode region,
the first element including at least one selected from the group consisting of B, Ga, In, and Al,
the first electrode region including:
   a first region between the third partial region and the second electrode region in the second direction,
   a second region between the first semiconductor portion and the second electrode region in the first direction, and
   a third region between the second electrode region and the second semiconductor portion in the first direction, and
a first thickness of the first region along the second direction being 30 nm or more.

### Technical Proposal 2

The semiconductor device according to Technical proposal 1, wherein
a first ratio of a difference between a first maximum value of a concentration of the first element in the first region and a first minimum value of the concentration of the first element in the first region to the first minimum value is 0.1 or less.

### Technical Proposal 3

The semiconductor device according to Technical proposal 2, wherein
the first concentration is ½ of a sum of the first maximum value and the first minimum value.

### Technical Proposal 4

The semiconductor device according to Technical proposal 2 or 3, wherein
the first concentration is not less than 5×10²⁰ cm⁻³ and not more than 5×10²¹ cm⁻³.

### Technical Proposal 5

The semiconductor device according to any one of Technical proposals 1-4, wherein
a second thickness of the second region along the first direction is not less than 30 nm.

### Technical Proposal 6

The semiconductor device according to Technical proposal 5, wherein
the second thickness is 150 nm or less.

### Technical Proposal 7

The semiconductor device according to Technical proposal 5 or 6, wherein
a second ratio of a difference between a second maximum value of the concentration of the first element in the second region and a second minimum value of the concentration of the first element in the second region to the second minimum value is 0.1 or less.

### Technical Proposal 8

The semiconductor device according to Technical proposal 7, wherein
the second maximum value is not less than 5×10²⁰ cm⁻³ and not more than 5×10²¹ cm⁻³.

### Technical Proposal 9

The semiconductor device according to any one of Technical proposals 1-8, wherein
a third thickness of the third region along the first direction is 30 nm or more.

### Technical Proposal 10

The semiconductor device according to Technical proposal 9, wherein
a third ratio of a difference between a third maximum value of the concentration of the first element in the third region and a third minimum value of the concentration of the first element in the third region to the third minimum value is 0.1 or less.

### Technical Proposal 11

The semiconductor device according to Technical proposal 10, wherein
the third maximum value is not less than 5×10²⁰ cm⁻³ and not more than 5×10²¹ cm⁻³.

### Technical Proposal 12

The semiconductor device according to any one of Technical proposals 1-11, wherein
the first concentration is not more than 1.3 times and not more than 30 times the second concentration.

### Technical Proposal 13

The semiconductor device according to any one of Technical proposals 1-3, wherein
the second concentration is not more than 1.3 times and not more than 30 times the first concentration.

### Technical Proposal 14

The semiconductor device according to any one of Technical proposals 1-13, wherein
a second size of a second crystal grain in the second electrode region is larger than a first size of a first crystal grain in the first electrode region.

### Technical Proposal 15

The semiconductor device according to any one of Technical proposals 1-14, further comprising:
a first compound member including Al_{z1}Ga_{1-z1}N (x2<z1≤1),
the first compound member including
   a first compound region between the third partial region and the first insulating member in the second direction,
   a second compound region between the first semiconductor portion and the first insulating member in the first direction, and
   a third compound region between the first insulating member and the second semiconductor portion in the first direction.

### Technical Proposal 16

The semiconductor device according to any one of Technical proposals 1-15, wherein
the third electrode includes
   a first face facing the third partial region in the second direction, and
   a second face facing the first semiconductor portion in the first direction, and
the second face is inclined with respect to the first face.

### Technical Proposal 17

The semiconductor device according to any one of Technical proposals 1-16, further comprising:
a first conductive layer; and
a second conductive layer,
the second electrode region being provided between the first electrode region and the second conductive layer,
the first conductive layer being between the second electrode region and the second conductive layer,
the first conductive layer including at least one selected from the group consisting of Ti, Ta, and W, and
the second conductive layer including at least one selected from the group consisting of Al, Cu, Au, Ag, and Ni.

### Technical Proposal 18

The semiconductor device according to any one of Technical proposals 1-16, wherein
the first thickness is 150 nm or less.

### Technical Proposal 19

The semiconductor device according to any one of Technical proposals 1-18, wherein
at least a part of the first electrode region is between the fourth partial region and the fifth partial region in the first direction.

### Technical Proposal 20

A method for manufacturing a semiconductor device, comprising:
preparing a semiconductor member including a first semiconductor layer including Alₓ₁Ga₁₋ₓ₁N (0≤x1<1), and a second semiconductor layer including Alₓ₂Ga₁₋ₓ₂N (0<x2≤1, x1<x2);
removing a part of the second semiconductor layer to form a hole reaching the first semiconductor layer;
forming a first electrode region on a bottom of the hole and a side face of the hole, the first electrode region including a first element and silicon, the first element including at least one selected from the group consisting of B, Ga, In, and Al, a first thickness of the first electrode region being 30 nm or more;
forming a second electrode region including silicon on the first electrode region; and
introducing the first element into the second electrode region.

According to the embodiment, it is possible to provide a semiconductor device whose characteristics can be improved and a method for manufacturing the same.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the semiconductor device such as electrodes, semiconductor members, semiconductor layers, compound members, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices and all methods for manufacturing the same practicable by an appropriate design modification by one skilled in the art based on the semiconductor devices and the methods for manufacturing the same described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first electrode;
a second electrode;
a third electrode including silicon, a position of the third electrode in a first direction from the first electrode to the second electrode being between a position of the first electrode in the first direction and a position of the second electrode in the first direction, the third electrode including a first electrode region and a second electrode region;
a semiconductor member including a first semiconductor layer and a second semiconductor layer,
the first semiconductor layer including Alₓ₁Ga₁₋ₓ₁N (0≤x1<1), the first semiconductor layer including a first partial region, a second partial region, a third partial region, a fourth partial region, and a fifth partial region, a second direction from the first partial region to the first electrode crossing the first direction, a direction from the second partial region to the second electrode being along the second direction, a direction from the third partial region to the third electrode being along the second direction, a position of the fourth partial region in the first direction being between a position of the first partial region in the first direction and a position of the third partial region in the first direction, a position of the fifth partial region in the first direction being between the position of the third partial region in the first direction and a position of the second partial region in the first direction;
the second semiconductor layer including Alₓ₂Ga₁₋ₓ₂N (0<x2≤1, x1<x2), the second semiconductor layer including a first semiconductor portion and a second semiconductor portion, a direction from the fourth partial region to the first semiconductor portion being along the second direction, a direction from the fifth partial region to the second semiconductor portion being along the second direction; and 0
a first insulating member provided between the semiconductor member and the third electrode;
a first concentration of a first element in the first electrode region being different from a second concentration of the first element in the second electrode region,
the first element including at least one selected from the group consisting of B, Ga, In, and Al,
the first electrode region including:
a first region between the third partial region and the second electrode region in the second direction,
a second region between the first semiconductor portion and the second electrode region in the first direction, and
a third region between the second electrode region and the second semiconductor portion in the first direction, and
a first thickness of the first region along the second direction being 30 nm or more.

2. The device according to claim 1, wherein
a first ratio of a difference between a first maximum value of a concentration of the first element in the first region and a first minimum value of the concentration of the first element in the first region to the first minimum value is 0.1 or less.

3. The device according to claim 2, wherein
the first concentration is ½ of a sum of the first maximum value and the first minimum value.

4. The device according to claim 2, wherein
the first concentration is not less than 5×10²⁰ cm⁻³ and not more than 5×10²¹ cm⁻³.

5. The device according to claim 1, wherein
a second thickness of the second region along the first direction is not less than 30 nm.

6. The device according to claim 5, wherein
the second thickness is 150 nm or less.

7. The device according to claim 5, wherein
a second ratio of a difference between a second maximum value of the concentration of the first element in the second region and a second minimum value of the concentration of the first element in the second region to the second minimum value is 0.1 or less.

8. The device according to claim 7, wherein
the second maximum value is not less than 5×10²⁰ cm⁻³ and not more than 5×10²¹ cm⁻³.

9. The device according to claim 1, wherein
a third thickness of the third region along the first direction is 30 nm or more.

10. The device according to claim 9, wherein
a third ratio of a difference between a third maximum value of the concentration of the first element in the third region and a third minimum value of the concentration of the first element in the third region to the third minimum value is 0.1 or less.

11. The device according to claim 10, wherein
the third maximum value is not less than 5×10²⁰ cm⁻³ and not more than 5×10²¹ cm⁻³.

12. The device according to claim 1, wherein
the first concentration is not more than 1.3 times and not more than 30 times the second concentration.

13. The device according to claim 1, wherein
the second concentration is not more than 1.3 times and not more than 30 times the first concentration.

14. The device according to claim 1, wherein
a second size of a second crystal grain in the second electrode region is larger than a first size of a first crystal grain in the first electrode region.

15. The device according to claim 1, further comprising:
a first compound member including Al_{z1}Ga_{1-z1}N (x2<z1<1,
the first compound member including
a first compound region between the third partial region and the first insulating member in the second direction,
a second compound region between the first semiconductor portion and the first insulating member in the first direction, and
a third compound region between the first insulating member and the second semiconductor portion in the first direction.

16. The device according to claim 1, wherein
the third electrode includes
a first face facing the third partial region in the second direction, and
a second face facing the first semiconductor portion in the first direction, and
the second face is inclined with respect to the first face.

17. The device according to claim 1, further comprising:
a first conductive layer; and
a second conductive layer,
the second electrode region being provided between the first electrode region and the second conductive layer,
the first conductive layer being between the second electrode region and the second conductive layer,
the first conductive layer including at least one selected from the group consisting of Ti, Ta, and W, and
the second conductive layer including at least one selected from the group consisting of Al, Cu, Au, Ag, and Ni.

18. The device according to claim 1, wherein
the first thickness is 150 nm or less.

19. The device according to claim 1, wherein
at least a part of the first electrode region is between the fourth partial region and the fifth partial region in the first direction.

20. A method for manufacturing a semiconductor device, comprising:
preparing a semiconductor member including a first semiconductor layer including Al^{x1}Ga₁₋ₓ₁N (0≤x1<1), and a second semiconductor layer including Al^{x2}Ga₁₋ₓ₂N (0<x2≤1, x1<x2);
removing a part of the second semiconductor layer to form a hole reaching the first semiconductor layer;
forming a first electrode region on a bottom of the hole and a side face of the hole, the first electrode region including a first element and silicon, the first element including at least one selected from the group consisting of B, Ga, In, and Al, a first thickness of the first electrode region being 30 nm or more;
forming a second electrode region including silicon on the first electrode region; and
introducing the first element into the second electrode region.
